(19) United States
(12) Patent Application Publication
(10) Pub. No.: US 2026/0160798 A1
(43) Pub. Date: Jun. 11, 2026

(54) TARGET YIELD CORRECTION METHOD, CORRECTION DEVICE AND COMPUTER READABLE STORAGE MEDIA

(71) Applicant: Nuvoton Technology Corporation, Hsinchu Science Park (TW)

(72) Inventor: Cheng-Han TSAI, Hsinchu Science Park (TW)

(21) Appl. No.: 19/386,577

(22) Filed: Nov. 12, 2025

(30) Foreign Application Priority Data
Dec. 10, 2024 (TW) 113147769

(51) Int. Cl. G01R 31/28

(52) U.S. Cl. CPC G01R 31/2831

(57) ABSTRACT

A target yield correction method is provided. A plurality of yields of a plurality of first products in a plurality of wafers and a plurality of sizes of the first products in the wafers are obtained. The yields are divided into a plurality of groups according to sizes of the first products. The yields of each group are averaged to generate an average yield. The average yields and the sizes are calculated to generate a plurality of defect density values. The defect density values are input into a machine learning model to remove at least one defect density value that does not meet a predetermined standard. A baseline curve is generated according to the remaining defect density values. The baseline curve and the sizes are calculated to generate a plurality of target yields. Each target yield corresponds to one of the sizes.

### CROSS REFERENCE TO RELATED APPLICATIONS

This Application claims priority of Taiwan Patent Application No. 113147769, filed on Dec. 10, 2024, the entirety of which is incorporated by reference herein.

### TECHNICAL FIELD

The present disclosure relates to a correction method, and, in particular, it relates to a correction method that corrects a target yield.

### BACKGROUND

The standard yield of general products is determined by the defect density (D0) value of the wafer manufacturing plant. However, the D0 value is a fixed value. If the D0value is used to estimate the yield of all products, distortion problems may arise.

### BRIEF SUMMARY

A target yield correction method is provided. An exemplary embodiment of the target yield correction method is described in the following paragraph. A plurality of yields of a plurality of first products in a plurality of wafers and a plurality of sizes of the first products in the wafers are obtained. The yields are divided into a plurality of groups according to sizes of the first products. The yields of each group are averaged to generate an average yield. The average yields and the sizes are calculated to generate a plurality of defect density values. The defect density values are input into a machine learning model to remove at least one defect density value that does not meet a predetermined standard. A baseline curve is generated according to the remaining defect density values. The baseline curve and the sizes are calculated to generate a plurality of target yields. Each target yield corresponds to one of the sizes.

An embodiment of the present disclosure provides a correction device comprises an input memory, an output memory, a storage circuit and a processing circuit. The input memory stores a plurality of yields of a plurality of first products in a plurality of wafers and a plurality of sizes of the first products in the wafers. Each wafer comprises a plurality of chips. Each chip comprises the first product. The output memory stores a plurality of target yields. The storage circuit stores a machine learning model. The processing circuit accesses the input memory to read the yields and the sizes and divides the yields into a plurality of groups according to sizes of the first products. The processing circuit averages the yields of each group to generate an average yield and calculates the average yields and the sizes of the first products to generate a plurality of defect density values. The processing circuit loads the machine learning model stored in the storage circuit and inputs the defect density values into the machine learning model. The machine learning model removes at least one defect density value that does not meet a predetermined standard. The machine learning model generates a baseline curve according to the remaining defect density values and calculates the baseline curve and the sizes of the first products to generate the target yields. Each target yield corresponds to one of the sizes. The processing circuit writes the target yields to the output memory.

An embodiment of the present disclosure provides a computer readable storage media storing a program code. In response to the program code being executed by a computer, the computer performs steps. The steps comprise obtaining a plurality of yields of a plurality of first products in a plurality of wafers and a plurality of sizes of the first products in the wafers. The steps comprise dividing the yields into a plurality of groups according to sizes of the first products. The steps comprise averaging the yields of each group to generate an average yield. The steps comprise calculating the average yields and the sizes to generate a plurality of defect density values. The steps comprise inputting the defect density values into a machine learning model to remove at least one defect density value that does not meet a predetermined standard. The steps comprise generating a baseline curve according to the remaining defect density values. The steps comprise calculating the baseline curve and the sizes to generate a plurality of target yields. Each target yield corresponds to one of the sizes.

A target yield correction method may be practiced by the systems which have hardware or firmware capable of performing particular functions and may take the form of program code embodied in a tangible media. When the program code is loaded into and executed by an electronic device, a processor, a computer or a machine, the electronic device, the processor, the computer or the machine becomes a correction device for practicing the disclosed method.

### BRIEF DESCRIPTION OF THE DRAWINGS

The present disclosure can be more fully understood by reading the subsequent detailed description and examples with references made to the accompanying drawings, wherein:

FIG. 1 is a flowchart of an exemplary embodiment of a target yield correction method according to various aspects of the present disclosure;

FIG. 2 is a schematic diagram of an exemplary embodiment of defect density values;

FIG. 3 shows the relationship between defect density values and sizes for specific products with different manufacturing specifications; and

FIG. 4 is a schematic diagram of an exemplary embodiment of a correction device according to various aspects of the present disclosure.

### DETAILED DESCRIPTION

The present disclosure will be described with respect to particular embodiments and with reference to certain drawings, but the disclosure is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the present disclosure.

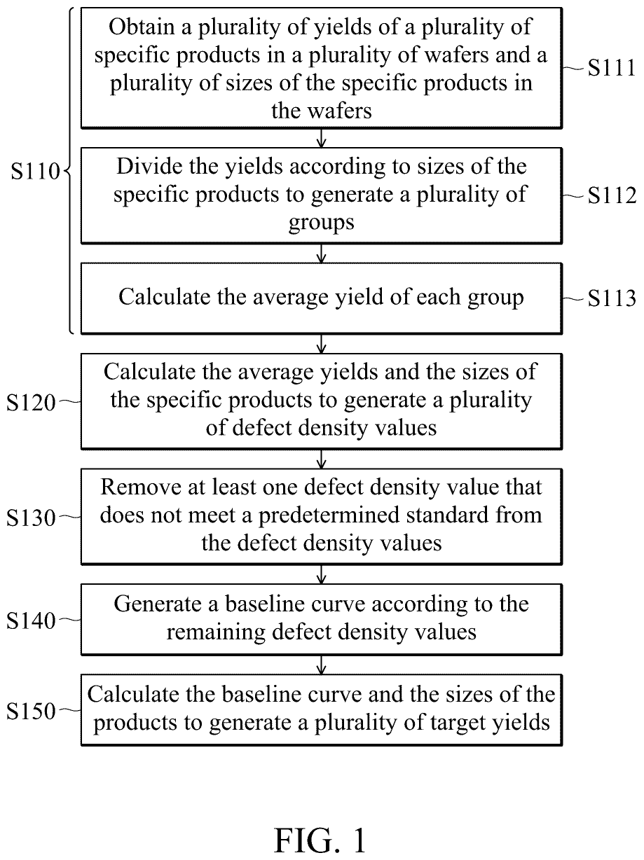

FIG. 1 is a flowchart of an exemplary embodiment of a target yield correction method according to various aspects of the present disclosure. The target yield correction may take the form of a program code embodied in a computer readable storage media. When the program code is loaded into and executed by a machine such as a computer readable storage media, the machine thereby becomes a correction device for practicing the target yield correction method.

First, the average yields of a plurality of wafers are calculated (step S110). In this embodiment, step S110 comprises steps S111˜S113. Step S111 obtains a plurality of yields of a plurality of specific products (referred to as first products) in a plurality of wafers and a plurality of sizes of the specific products in the wafers. In some embodiments, each wafer comprises a plurality of chips. Each chip comprises the specific product. The type of specific product is not limited in the present disclosure. Any circuit on the chip can be regarded as a specific product. For example, the specific product may be a memory, such as a SRAM, a flash, or a functional circuit, such as an ADC or a DAC.

In one embodiment, after the wafer manufacturing plant completes the process of each batch of wafers, the IC design plant will perform a chip probe (CP) test on each wafer in each batch to obtain the yield of each wafer. For example, assume that each batch of wafers has 25 wafers. In this case, step S111 may collect the yields of the specific products (such as SRAMs) from 10 batches of wafers (a total of 250 wafers). The size of the specific products in the same batch of wafers is the same, but may be different from the size of the specific products in another batch of wafers. Therefore, step S111 collects multiple yields and multiple sizes of the specific products in multiple wafers.

Next, the yields are divided according to sizes of the specific products to generate a plurality of groups (step S112). In one embodiment, the yields of the specific products with the same size are classified into the same group. For example, assume that each of the specific products in the first batch of wafers has a first size, each of the specific products in the second batch of wafers has a second size, each of the specific products in the third batch of wafers has the first size, each of the specific products in the fourth batch of wafers has the second size, and each of the specific products in the fifth batch of wafers has a third size. In this case, step S112 classifies the yield (such as 85%) of the specific products in the first batch of wafers and the yield (such as 90%) of the specific products in the third batch of wafers into a first group. Step S112 classifies the yield (such as 97%) of the specific products in the second batch of wafers and the yield (such as 97%) of the specific products in the fourth batch of wafers into a second group, and classifies the yield (such as 94%) of the specific products in the fifth batch of wafers into a third group.

The average yield of each group is calculated (step S113). For example, if the yields of the first group are 85% and 90%, after calculation in step S113, the average yield of the first group is 87.5%. Similarly, if the yields of the second group are 97% and 97%, after calculation in step S113, the average yield of the second group is 97%.

Next, the average yields and the sizes of the specific products are calculated to generate a plurality of defect density values (step S120). The present disclosure does not limit how the average yields and the sizes are calculated in step S120. In one embodiment, step S120 utilizes an algorithm such as a Poisson model, a Murphy model, an Exponential model, or a Seeds model to calculate the average yields and the sizes to generate a plurality of defect density (D0) values.

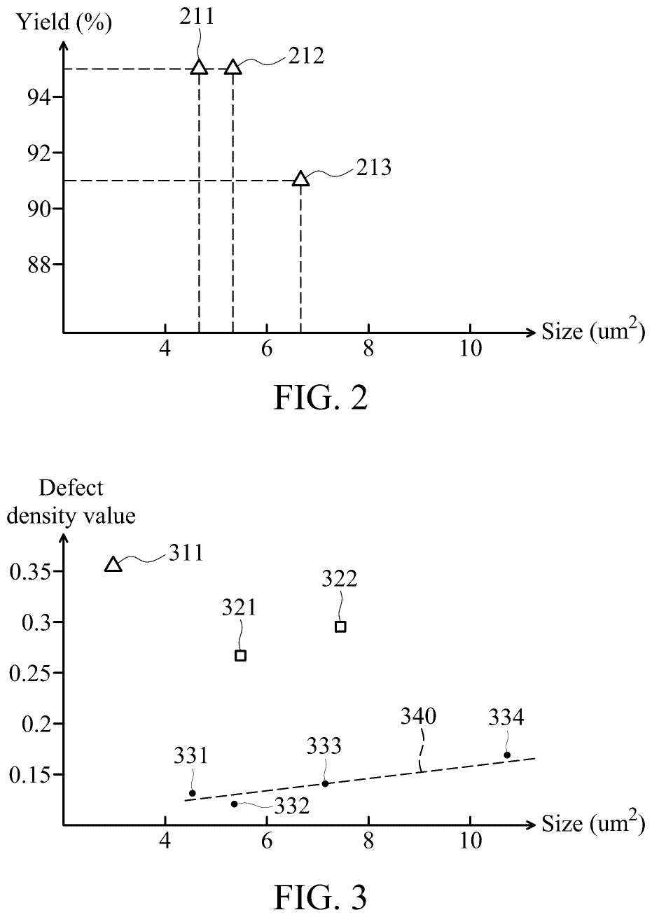

FIG. 2 is a schematic diagram of an exemplary embodiment of defect density values. Assume that after calculation in step S120, the defect density values 211˜213 are obtained. As shown in FIG. 2, when the size of a specific product is between 4 μm²˜5 μm² and the yield of the specific product is greater than 94%, after calculation in step S120, the defect density value 211 can be obtained. When the size of a specific product is between 5 μm²˜6 μm² and the yield of the specific product is greater than 94%, after calculation in step S120, the defect density value 212 can be obtained. When the size of a specific product is between 6 μm²˜7 μm² and the yield of the specific product is between 90%˜92%, after calculation in step S120, the defect density value 213 can be obtained.

FIG. 3 shows the relationship between the defect density values and the sizes for specific products with different manufacturing specifications. Assume that a specific product 311 has a first manufacturing specification, for example, the specific product 311 is produced by a process which has 43 mask layers. The specific products 321 and 322 have a second manufacturing specification, for example, the specific products 321 and 322 are produced by a process which has 44 mask layers. The specific products 331˜334 have a third manufacturing specification, for example, the specific products 331˜334 are produced by a process which has 45 mask layers.

In FIG. 3, the defect density value of the specific product 311 is approximately 0.35. The defect density values of the specific products 321 and 322 are approximately between 0.25˜0.3. The defect density values of the specific products 331˜334 are approximately below 0.2. In this case, the specific products 311, 321, 322, and 331˜334 are of the same. For example, each of the specific products 311, 321, 322, and 331˜334 is a SRAM.

Next, at least one defect density value that does not meet a predetermined standard is removed from the defect density values (step S130). In one embodiment, the defect density values obtained in step S120 are input into a machine learning model. The machine learning model removes at least one defect density values that does not meet a predetermined standard.

Taking FIG. 3 as an example, the number of mask layers for the specific products 321 and 322 (e.g., 44 mask layers) is smaller than the number of mask layers for the specific products 331˜334 (e.g., 45 mask layers). Theoretically, the defect density values of the specific products 321 and 322 should be smaller than the defect density values of the specific products 331˜334. However, shown in FIG. 3, the defect density values of the specific products 321 and 322 are greater than the defect density values of the specific products 331˜334. Since the defect density values of specific products 321 and 322 are unqualified, the machine learning model removes the defect density values of specific products 321 and 322.

In addition, the size of the specific product 311 (less than 4 μm²) is smaller than the size of the specific products 331˜334 (greater than 4 μm²). Theoretically, the defect density value of the specific product 311 should be smaller than the defect density values of the specific products 331˜334. Actually, the defect density value of the specific product 311 is greater than the defect density values of the specific products 331˜334. Furthermore, the number of mask layers of the specific product 311 (such as 43 mask layers) is smaller than the number of mask layers of the specific products 331˜334 (such as 45 mask layers). Theoretically, the defect density value of the specific product 311 should be smaller than the defect density value of the specific products 331˜334. In fact, the defect density value of the specific product 311 is greater than the defect density value of the specific products 331˜334. Since the defect density value of the specific product 311 violates two standards, it can be determined that the defect density value of the specific product 311 is an unqualified performance. Therefore, the machine learning model removes the defect density value of the specific product 311.

In other embodiments, the defect density value may affected by some factors which comprises the size of the product (or referred to as a chip area), the size of memory cell, a process specification (or referred to as a cell rule or a cell version), such as 0.18 process, 0.16 process, 0.075 process, and the number of mask layers. For example, when the product has a large size or a large number of mask layers, the defect density value of the product will be greater. Therefore, the machine learning model determines whether the defect density value generated in step S120 is reasonable according to the factors affecting the defect density value, and removes unreasonable defect density values.

Next, a baseline curve is generated according to the remaining defect density values (step S140). Taking FIG. 3 as an example, since the machine learning model removes the defect density values of the products 311, 321, and 322, only the defect density values of the products 331˜334 remain. Therefore, step S140 generates a baseline curve 340 according to the defect density values of the products 331˜334.

The baseline curve and the sizes of the products are calculated to generate a plurality of target yields (step S150). In this embodiment, each target yield corresponds to one of the sizes. In some embodiments, steps S110˜S150 are repeated to add new products that meet the predetermined standard into the calculation, dynamically modifying the baseline curve 340 so that the target yield is closer to the yield of the original product.

For example, assume that a wafer manufacturer informs that the yield of a specific product in a batch of wafers is 95%. After a testing process, the yield of the specific product in the batch of wafers is only 90%. The reason for the decline in yield is that the test machine or the probe card is unstable to cause an overkill event which reduces the yield of the specific product during the testing process. Therefore, the yield (90%) of the specific product may be unreasonable.

In order to find a reasonable target yield, step S110 first obtains the average yield of the wafers, and then uses a specific algorithm to calculate multiple defect density values according to the average yield and the sizes of the products (step S120). A machine learning model is used to remove some defect density values that do not meet the requirements. The remaining defect density values that meet the requirements are used to calculate the reasonable target yield of the products at different sizes. By continuously correcting the target yield, the target yield is closer to the actual yield of the product and the current status of the process.

In other embodiments, when step S112 divides the yields according to the different sizes of the products, step S112 further removes the yields that are lower than a threshold value among the yields. For example, among 250 wafers, if the yields of some wafers are outlier, such as lower than 60%, it means that the yields (lower than 60%) of these wafers are not worth referring to. Therefore, step S112 removes the yield that is too low. In one embodiment, step S112 inputs the multiple yields and multiple sizes obtained in step S111 into a machine learning model. The machine learning model analyzes the yields and removes the low yields. Then, the machine learning model classifies the remaining yields according to sizes of the specific products to generate multiple groups.

In some embodiments, the target yields generated in step S150 are used to determine whether the specific products in a plurality of wafers to be tested are qualified. In this case, one of the target yields is selected as a specific target yield according to the size of the specific product of the wafer to be tested. For example, if the size of the specific product in a wafer to be tested is 4 μm², since each target yield in step S150 corresponds to a specific size, the target yield with a size of 4 μm² is selected as a specific yield. By selecting an appropriate target yield according to the size of the product, it is possible to avoid mistakenly judging a qualified product as a defective product.

Next, it is determined whether the yield of the specific product of the wafer to be tested is greater than the specific target yield. When the yield of the specific product of the first of the wafers to be tested is lower than the specific target yield, the first wafer to be tested is highlighted. In one embodiment, an analysis improvement operation is performed on the highlighted first wafer to find out the reason for the low yield.

However, when the yield of a specific product of the second wafer to be tested is not lower than the specific target yield, the yield and size of the specific product of the second wafer to be tested are input into the machine learning model. The machine learning model corrects the defect density values according to the yield and size of the specific product of the second wafer to be tested. Since the machine learning model gradually incorporates the yield and size of the specific product whose yield meets the standard, the accuracy of the target yield can be increased.

In one embodiment, before using the machine learning model, a training operation is first performed on the machine learning model. For example, training data is input into the machine learning model to train the machine learning model to remove defect density values that do not meet a predetermined standard. In one embodiment, the training data includes a plurality of sample sizes, a plurality of numbers of mask layers, and a plurality of process specifications. The machine learning model establishes a plurality of correlations between the sample sizes, the number of mask layers, and the process specifications. After completing the training operation, the machine learning model finds and removes at least one defect density value that does not meet the predetermined standard from the defect density values according to the correlations. In another embodiment, the training data includes an outlier threshold value. In this case, the machine learning model establishes a removal standard according to the outlier threshold value to remove the outlier yield in step S112.

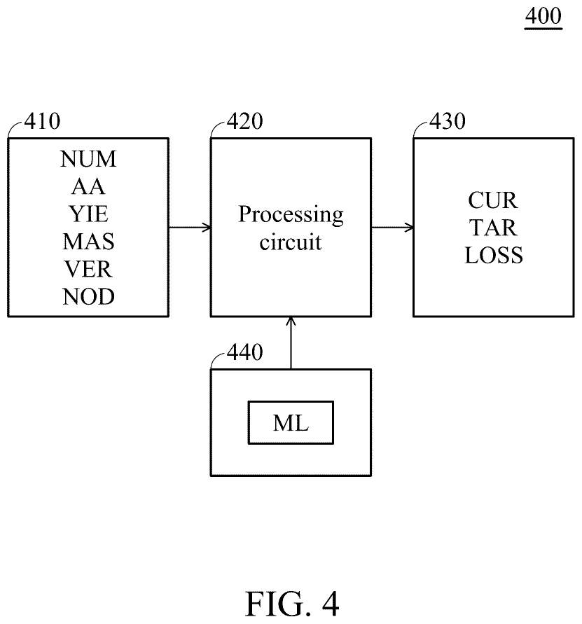

FIG. 4 is a schematic diagram of an exemplary embodiment of a correction device according to various aspects of the present disclosure. As shown in FIG. 4, the correction device 400 comprises an input memory 410, a processing circuit 420, an output memory 430, and a storage circuit 440. A machine learning model generates target yield data according to the data stored in the input memory 410.

For example, the input memory 410 stores a product type NUM, such as a SRAM or a flash. The input memory 410 further stores product sizes (or referred to as a product chip area AA, such as the sizes of SRAMs. In another embodiment, the input memory 410 stores the yields (or referred to as the product yields) YIE of the specific products in a plurality of wafers. In this case, all the chips on each wafer have the specific product. The yield of each specific product is the yield of the corresponding wafer. Therefore, each wafer has a yield. In some embodiments, the input memory 410 further stores the number of product mask layers MAS and the process used cell size/version VER, such as 90 nm, or 55 nm. In other embodiments, the input memory 410 further stores the process node NOD.

The processing circuit 420 reads the yields YIE and the product sizes AA stored in the input memory 410 and classifies the yields YIE of the wafers according to the product sizes AA to generate a plurality of groups. In one embodiment, the processing circuit 420 loads a machine learning model ML stored in the storage circuit 440 and inputs the yields YIE and product sizes AA into the machine learning model ML. In this case, the machine learning model ML removes outlier yields and then classifies the remaining yields.

In some embodiments, the processing circuit 420 calculates an average yield for each yield group and inputs the average yields and the product sizes AA into the machine learning model ML. The machine learning model ML calculates the average yields and the product sizes AA to generate a plurality of defect density (D0) values. In one embodiment, the processing circuit 420 inputs the defect density (D0) values into the machine learning model ML. The machine learning model ML calculates a correlation between the defect density (D0) values and the product sizes AA to generate a baseline curve CUR.

The machine learning model ML removes at least one defect density (D0) values that does not meet a predetermined standard. Taking FIG. 3 as an example, the number of mask layers of the products 321 and 322 (e.g., 44 mask layers) is lower than the number of mask layers of the products 331˜334 (e.g., 45 layers), but the defect density values of products 321 and 322 are higher than the defect density values of the products 331˜334. It means that the defect density values of the products 321 and 322 do not meet a predetermined standard. Therefore, the machine learning model ML removes the defect density values of the products 321 and 322.

The machine learning model ML generates a baseline curve CUR according to the remaining defect density values (such as the defect density values of the products 331˜334 in FIG. 3). In one embodiment, the processing circuit 420 writes the baseline curve CUR to the output memory 430. In other embodiments, the processing circuit 420 inputs the baseline curve CUR and the product sizes AA into the machine learning model ML. The machine learning model ML calculates the baseline curve CUR and the product sizes AA to generate a plurality of target yields TAR. In this embodiment, each target yield corresponds to one of the product sizes AA. In addition, the processing circuit 420 may write the target yield TAR to the output memory 430.

In some embodiments, the machine learning model ML determines whether the yield of subsequent product can reach the corresponding target yield according to the target yield TAR. When the yield of a specific product of a wafer does not meet the corresponding target yield, the machine learning model ML marks the wafer and outputs the marking result LOSS to the output memory 430. Therefore, the tester or the test apparatus can know which wafer has an abnormality according to the data stored in the output memory 430. The tester or the test apparatus may analyze and process the abnormal wafer to find out the reason for the low yield.

The target yield correction methods, or certain aspects or portions thereof, may take the form of a program code (i.e., executable instructions) embodied in tangible media, such as floppy diskettes, CD-ROMS, hard drives, or any other machine-readable storage medium, wherein, when the program code is loaded into and executed by a machine such as a computer, the machine thereby becomes a correction device for practicing the methods. The methods may also be embodied in the form of a program code transmitted over some transmission medium, such as electrical wiring or cabling, through fiber optics, or via any other form of transmission, wherein, when the program code is received and loaded into and executed by a machine such as a computer, the machine becomes a correction device for practicing the disclosed methods. When implemented on a general-purpose processor, the program code combines with the processor to provide a unique apparatus that operates analogously to application-specific logic circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will be understood that although the terms “first,” “second,” etc. may be used herein to describe various elements, these elements should not be limited by these terms. These terms are only used to distinguish one element from another.

While the disclosure has been described by way of example and in terms of the preferred embodiments, it should be understood that the disclosure is not limited to the disclosed embodiments. On the contrary, it is intended to cover various modifications and similar arrangements. Therefore, the scope of the appended claims should be accorded the broadest interpretation so as to encompass all such modifications and similar arrangements.

What is claimed is:

1. A target yield correction method comprising:
obtaining a plurality of yields of a plurality of first products in a plurality of wafers and a plurality of sizes of the first products in the wafers;
dividing the yields into a plurality of groups according to sizes of the first products;
averaging the yields of each group to generate an average yield;
calculating the average yields and the sizes to generate a plurality of defect density values;
inputting the defect density values into a machine learning model to remove at least one defect density value that does not meet a predetermined standard;
generating a baseline curve according to the remaining defect density values; and
calculating the baseline curve and the sizes to generate a plurality of target yields,
wherein each target yield corresponds to one of the sizes.

2. The target yield correction method as claimed in claim 1, wherein the step of dividing the yields into a plurality of groups according to sizes of the first products comprises:
removing at least one yield which is lower than a threshold value; and
dividing the remaining yields which are not lower than the threshold value according to sizes of the first products to generate the groups.

3. The target yield correction method as claimed in claim 2, wherein the step of dividing the yields into a plurality of groups according to sizes of the first products comprises:
inputting the yields into the machine learning model, and
wherein the machine learning model removes at least one yield which is lower than the threshold value.

4. The target yield correction method as claimed in claim 3, further comprising:
inputting training data into the machine learning model to train the machine learning model to remove at least one defect density value that does not meet the predetermined standard.

5. The target yield correction method as claimed in claim 4, wherein:
the training data comprises a plurality of sample sizes, the number of mask layers, and a plurality of process specifications,
the machine learning model establishes a plurality of correlations between the sample sizes, the number of mask layers, and the process specifications, and
the machine learning model moves at least one defect density value that does not meet the predetermined standard according to the correlations.

6. The target yield correction method as claimed in claim 1, further comprising:
selecting one of the target yields as a specific target yield according to the size of a second product of a wafer to be tested;
determining whether the yield of the second product of the wafer to be tested is greater than the specific target yield; and
marking the wafer to be tested in response to the yield of the second product of the wafer to be tested not being greater than the specific target yield,
wherein the kind of second product is the same as the kind of first products.

7. The target yield correction method as claimed in claim 6, further comprising:
performing an analysis improvement operation on the wafer to be tested.

8. The target yield correction method as claimed in claim 6, wherein:
in response to the yield of the second product of the wafer to be tested being greater than the specific target yield, the yield and the size of the wafer to be tested are input into the machine learning model, and
the machine learning model corrects the defect density values according to the yield and the size of the wafer to be tested.

9. A correction device, comprising:
an input memory storing a plurality of yields of a plurality of first products in a plurality of wafers and a plurality of sizes of the first products in the plurality of wafers, wherein each wafer comprises a plurality of chips and each chip comprises the first product;
an output memory storing a plurality of target yields;
a storage circuit storing a machine learning model; and
a processing circuit accessing the input memory to read the yields and the sizes and dividing the yields into a plurality of groups according to sizes of the first products,
wherein:
the processing circuit averages the yields of each group to generate an average yield and calculates the average yields and the sizes to generate a plurality of defect density values,
the processing circuit loads the machine learning model stored in the storage circuit and inputs the defect density values into the machine learning model,
the machine learning model removes at least one defect density value that does not meet a predetermined standard,
the machine learning model generates a baseline curve according to the remaining defect density values and calculates the baseline curve and the sizes to generate the target yields,
each target yield corresponds to one of the sizes,
the processing circuit writes the target yields to the output memory.

10. The correction device as claimed in claim 9, wherein the processing circuit removes at least one yield which is lower than a threshold value and divides the remaining yields which are not lower than the threshold value according to sizes of first products to generate the groups.

11. The correction device as claimed in claim 9, wherein:
the processing circuit inputs the yields into the machine learning model,
the machine learning model removes at least one yield which is lower than a threshold value,
the machine learning model divides the remained yields which are not lower than the threshold value according to sizes of first products to generate the groups.

12. The correction device as claimed in claim 11, wherein the processing circuit inputs training data into the machine learning model to train the machine learning model to remove at least one defect density value that does not meet the predetermined standard.

13. The correction device as claimed in claim 12, wherein:
the training data comprises a plurality of sample sizes, the number of mask layers, and a plurality of process specifications,
the machine learning model establishes a plurality of correlations between the sample sizes, the number of mask layers, and the process specifications, and
the machine learning model removes at least one defect density value that does not meet the predetermined standard according to the correlations.

14. The correction device as claimed in claim 9, wherein:
the machine learning model selects one of the target yields as a specific target yield according to the size of a second product of a wafer to be tested,
the machine learning model determines whether the yield of the second product of the wafer to be tested is greater than the specific target yield;
in response to the yield of the second product of the wafer to be tested not being greater than the specific target yield, the machine learning model marks the wafer to be tested to generate a marking result,
the marking result is stored in the output memory,
the kind of second product is the same as the kind of first products.

15. The correction device as claimed in claim 14, wherein the output memory outputs the marking result to a test apparatus, and the test apparatus performs an analysis improvement operation on the wafer to be tested.

16. The correction device as claimed in claim 14, wherein:
in response to the yield of the second product of the wafer to be tested being greater than the specific target yield, the yield and the size of the wafer to be tested are input into the machine learning model, and
the machine learning model corrects the defect density values according to the yield and the size of the wafer to be tested.

17. The correction device as claimed in claim 9, wherein:
the output memory stores the baseline curve,
the processing circuit accesses the output memory to read the baseline curve and inputs the baseline curve into the machine learning model,
the processing circuit accesses the storage circuit to read the sizes and inputs the sizes into the machine learning model.

18. A computer readable storage media storing a program code, wherein in response to the program code being executed by a computer, the computer performs steps comprising:
obtaining a plurality of yields of a plurality of first products in a plurality of wafers and a plurality of sizes of the first products in the plurality of wafers;
dividing the yields into a plurality of groups according to sizes of the first products;
averaging the yields of each group to generate an average yield;
calculating the average yields and the sizes to generate a plurality of defect density values;
inputting the defect density values into a machine learning model to remove at least one defect density value that does not meet a predetermined standard;
generating a baseline curve according to the remaining defect density values; and
calculating the baseline curve and the sizes to generate a plurality of target yields,
wherein each target yield corresponds to one of the sizes.

19. The computer readable storage media as claimed in claim 18, wherein in response to the program code being executed by the computer, the computer further performs:
selecting one of the target yields as a specific target yield according to the size of a second product of a wafer to be tested;
determining whether the yield of the second product of the wafer to be tested is greater than the specific target yield;
marking the wafer to be tested to generate a marking result in response to the yield of the second product of the wafer to be tested not being greater than the specific target yield; and
outputting the marking result to a test apparatus,
wherein:
the test apparatus performs an analysis improvement operation on the wafer to be tested,
the kind of second product is the same as the kind of first products.

20. The computer readable storage media as claimed in claim 19, wherein:
in response to the yield of the second product of the wafer to be tested being greater than the specific target yield, the yield and the size of the wafer to be tested are input into the machine learning model, and
the machine learning model corrects the defect density values according to the yield and the size of the wafer to be tested.
